(19) United States
(12) Patent Application Publication
(10) Pub. No.: US 2012/0313173 A1
(43) Pub. Date: Dec. 13, 2012

(54) METHOD FOR ISOLATING RF FUNCTIONAL BLOCKS ON SILICON-ON-INSULATOR (SOI) SUBSTRATES

(75) Inventors: Carl Dickey, Browns Summit, NC (US); Nathaniel Peachey, Oak Ridge, NC (US); Robert Deuchars, Carlsbad, CA (US)

(73) Assignee: RF MICRO DEVICES, INC., Greensboro, NC (US)

(21) Appl. No.: 13/490,771

(22) Filed: Jun. 7, 2012

Related U.S. Application Data
(60) Provisional application No. 61/494,083, filed on Jun. 7, 2011.
(60) Provisional application No. 61/552,768, filed on Oct. 28, 2011.

(51) Int. Cl. H01L 27/12

(52) U.S. Cl. 257/347; 257/E27.112

(57) ABSTRACT

Buried implants are used to reduce RF (radio-frequency) coupling in a SOI (Silicon-on-insulator) circuit. These buried implants are located above and/or below the BOX (buried oxide) layer of the SOI circuit. These buried implants may completely enclose the PWELL (P-type well) of an NFET (N-type Field Effect Transistor).

### RELATED APPLICATIONS

This application claims the benefit of provisional patent applications Ser. No. 61/494,083 filed Jun. 7, 2011, and Ser. No. 61/552,768 filed Oct. 28, 2011, the disclosures of which are hereby incorporated herein by reference in their entirety.

### FIELD OF THE DISCLOSURE

This disclosure is directed to the field of reducing RF (radio-frequency) coupling in Silicon-on-insulator (SOI) circuits by using implants above and/or below the buried oxide (BOX) layer.

### BACKGROUND

Radio-Frequency (RF) circuits that are built in silicon technologies suffer from degraded performance due to coupling. This coupling results from the conduction of small portions of the RF signal in the semiconductor substrate. This coupling degrades such properties as: insertion loss, second and third order harmonics, and intermodulation distortion (IMD). This coupling can also lower the breakdown voltage of, for example, NMOS transistors due to transient signals lowering the snap-back voltage. Silicon-on-insulator (SOI) substrates greatly reduce this coupling by providing a non-conducting dielectric layer between the active devices and the substrate.

The substrate losses due to coupling can be further reduced if the substrate or handle wafer (located under the buried oxide layer) has a high resistivity. However, in low resistance substrate wafers the free carriers at the SiO₂/Si interface of the buried oxide (BOX) and the handle wafer can form a low resistance interface layer, as described in D. Lederer, R. Lobet, J. P. Raskin, “Enhanced High resistivity SOI wafers for RF applications,” 2004 IEEE International SOI Conference, 2004, pp. 46-47. This low resistance interface layer can significantly degrade RF performance, because the low resistance interface layer provides a conduction path that enhances the coupling between devices. While conduction through this conduction path appears small, this conduction causes a measurable degradation of device isolation and an increase in parameters such as insertion loss and intermodulation distortion (IMD).

One method to neutralize the free carriers at the BOX/handle wafer interface is to raise the doping level of the handle wafer slightly. The increased doping level can offset the impact of the free carriers at the interface. This increased doping level, however, can be a rather small process window since increasing the doping level will cause the negative side effect of increased conductivity of the handle wafer and increased coupling.

Additionally, coupling can be minimized by increasing the physical separation (spacing) between the devices in the thin SOI layer. However, there are physical and practical limits to increasing the spacing between devices since this increases the die area, and increases the cost of the product.

Attempts have been made to increase the isolation between devices on SOI substrates. One report suggests that placing vias through the BOX layer into p+(boron) implanted regions in the bulk wafer can improve isolation. See M. Kumar, Y. Tan, J. K. O. Sin, “Novel Isolation Structures for TFSOI Technology,” Electron Device Letters, 22(9) 2001, pp. 435-437.

Another approach has been to construct a deep substrate guard-ring where an n-type implant is placed in the bulk below the BOX layer around the devices to be isolated. See Y. Hiraoka, S. Matsumoto, T. Sakai, “New Substrate-Crosstalk Reduction Structure using SOI Substrates,” 2011 IEEE International SOI Conference, 2001, pp. 107-108. Vias drilled through the BOX layer make contact with the n-type guard ring.

Conventionally, other deep implants have been used in SOI substrates to build ESD (electro-static discharge) diodes below the BOX layer in order to take advantage of the large current carrying capability of a diode in bulk silicon. See Akram Salman, Mario Pelella, Stephen Beebe, Niraj Subba, “ESD Protection for SOI Technology using Under-the-BOX (Substrate) Diode Structure,” IEEE Transactions on Device and Materials Reliability, 6(2), June 2006, pp. 292-299. However, the presently disclosed deep implants for suppressing coupling differ in both purpose and construction from the conventional ESD implants.

While these conventional methods are typically employed to increase the RF isolation of SOI substrates, they are not adequate to suppress the coupling to the levels required by very high-performance RF circuits. Furthermore, none of these methods address the suppression of the free carriers at the interface region.

### SUMMARY

Negative properties such as intermodulation distortion and harmonic coupling degrade the functioning of RF circuits when an RF signal from a first transistor couples through the silicon-on-insulator SOI substrate handle wafer to a second transistor. The present disclosure provides several embodiments by which such RF coupling of active devices (such as transistors) through the SOI substrate can be reduced. To achieve this, an N-type implant (or a P-type implant) is placed above and/or below the buried oxide (BOX) layer of the SOI die. This implant increases the capacitance between the active devices and the substrate below the BOX layer, and/or shields and isolates the active devices from the substrate.

Those skilled in the art will appreciate the scope of the present disclosure and realize additional aspects thereof after reading the following detailed description in association with the accompanying drawings.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates conventional RF coupling of two transistors through the BOX layer and through the handle layer.

FIG. 2 illustrates a deep NWELL (first embodiment).

FIG. 3 illustrates a sub-BOX N-type layer (second embodiment).

FIG. 4 illustrates a contacted sub-BOX N-type layer (third embodiment).

FIG. 5 illustrates an electrical schematic of a contacted sub-BOX N-type layer (third embodiment).

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

In order to reduce RF frequency coupling in SOI circuits, additional isolation structures are needed. Concomitant to the appropriate isolation is the design of the structures such that the isolation structure itself becomes a transmission line to shunt the RF noise away from the neighboring active devices, optionally through a via. Described below are various embodiments of the present disclosure.

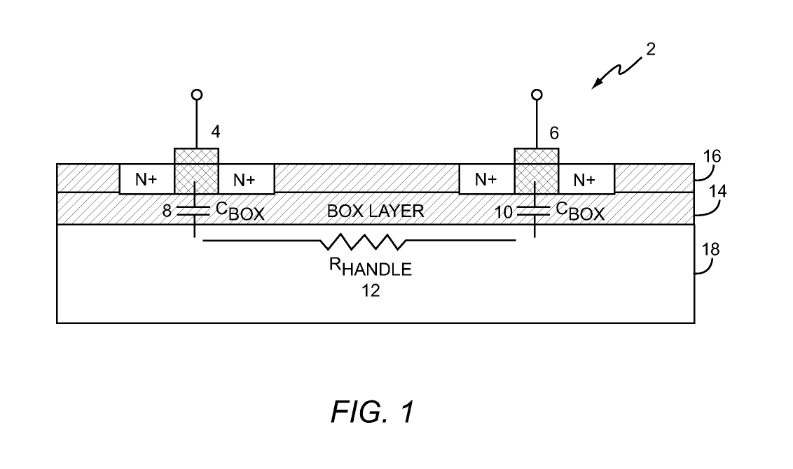

FIG. 1 illustrates conventional RF coupling of two transistors through the BOX layer and through the handle layer. Specifically, FIG. 1 illustrates a conventional SOI (Silicon-on-insulator) circuit with two NFETs (n-channel Field Effect Transistors), and with coupling of devices through the BOX layer and through the handle wafer.

Conventional RF circuit 2 includes: a first transistor NFET 4 and a second transistor NFET 6 in a thin silicon layer 16; a buried oxide (BOX) layer 14; and a handle layer (silicon layer or wafer) 18.

RF coupling occurs when an RF signal from first transistor 4 travels downward through the BOX layer 14 (having a capacitance CBOX 8), then sideways through the handle layer 18 (having a resistance Rhandle 12), then upwards through the BOX layer 14 (having a capacitance CBOX10) to the second transistor NFET 6. The capacitors CBOX 8 and CBOX10 are parasitic capacitors since they are the consequence of the BOX layer 14 separating the 2 silicon layers. RF coupling also occurs in the reverse direction.

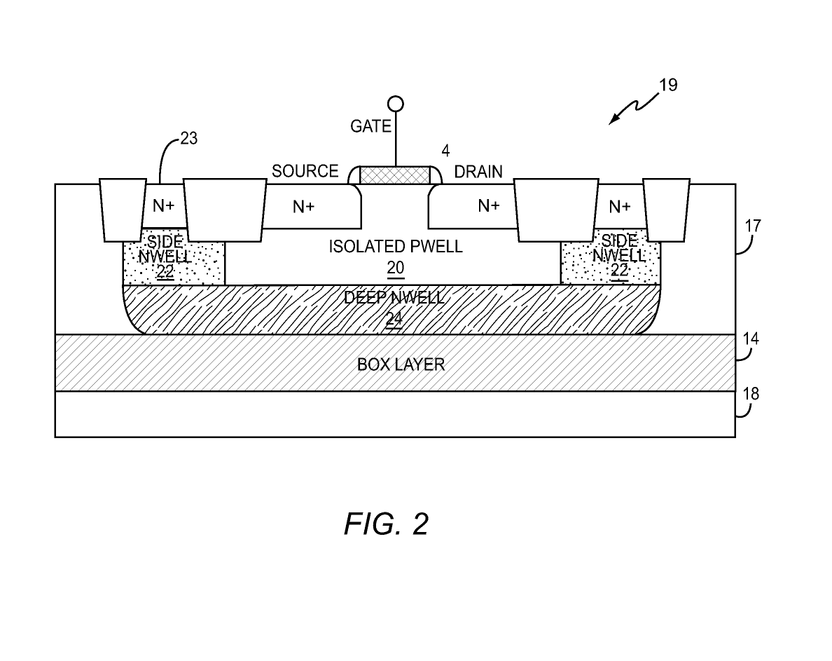

FIG. 2 illustrates a deep NWELL 24 (an N-type implant), which is a first embodiment. FIG. 2 is a thick SOI (Silicon-on-insulator) circuit having three layers: a thick silicon layer 17, a BOX layer 14, and a handle layer 18. Specifically, FIG. 2 illustrates an isolated PWELL 20 (a P-type portion of NFET 4), which is isolated from below by a deep N-type implant (deep NWELL 24) and bounded by an N-type implant (side NWELL 22) on all sides. Further, side NWELL 22 (and indirectly deep NWELL 24) may be contacted (and grounded or biased) through contact portion N+ 23.

Thus, the PWELL 20 of NFET 4 is isolated from coupling/communicating downwardly (towards and through BOX layer 14) by deep NWELL 24, and is optionally isolated from coupling/communicating sideways by NWELL 22.

It is preferable to have the deep NWELL 24 bounded on the bottom by the BOX layer. This reduces any parasitic area capacitance between the P-type silicon in the isolated PWELL 20 and the substrate or handle layer 18 below the BOX layer 14. In this configuration, the only substantial capacitance would be the sidewall capacitance between the N-type wall implants and the P-type silicon.

In order for this deep NWELL embodiment to function well, silicon layer 17 on top of BOX layer 14 must be thick enough (thick layer SOI) such that the N+ implants for the source and drain of transistor 4 do not extend downward all the way to deep NWELL 24. Otherwise, this structure would be inoperable because the source and drain would effectively short circuit through deep NWELL 24. In other words, PWELL 20 must isolate the source and the drain from deep NWELL 24.

In addition to isolating the PWELL 20 of transistor 4, the Deep NWELL could be biased (not shown) to further reduce coupling to any other devices.

While this first embodiment does not address the interface states between the BOX layer 14 and the handle wafer 18, it would reduce the coupling to this source of free carriers. The free carriers result from electrons or holes that are generated below the BOX layer and that can move freely at that interface region.

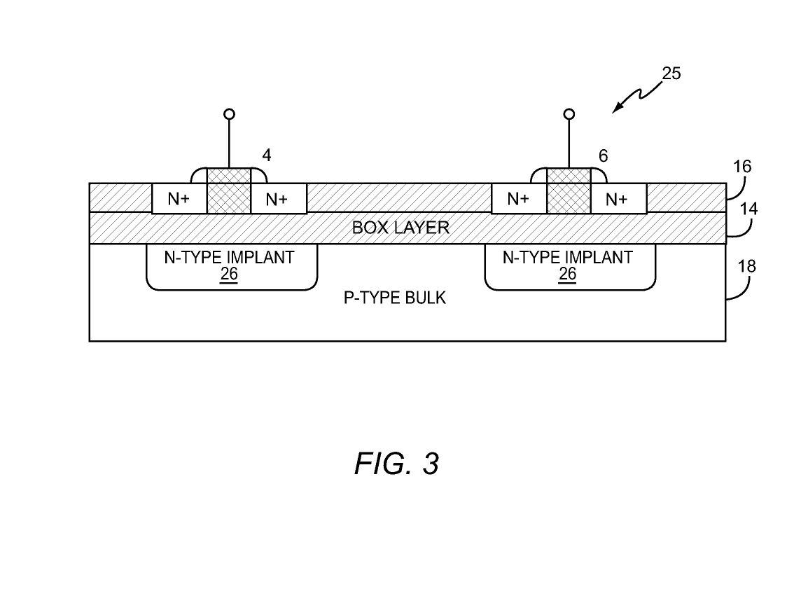

FIG. 3 illustrates a sub-BOX N-type layer (second embodiment). Similar to FIG. 1, FIG. 3 includes: a first transistor NFET 4 and a second transistor NFET 6 in a thin silicon layer 16; a buried oxide (BOX) layer 14; and a handle layer (silicon layer or wafer) 18. The handle layer 18 may optionally be P-type bulk silicon. In contrast to FIG. 1, FIG. 3 includes a first N-type implant 26 and preferably a second N-type implant 28, both located below the BOX layer.

In this second embodiment, one or more N-type implants 26 and 28 are placed below the BOX layer 14 (located “sub-BOX”). In this embodiment, a thin film SOI structure may be used (in contrast to FIG. 2 which requires thick film SOI). The devices that are built in this (thin) silicon layer 16 may be conventionally constructed using a typical thin film SOI process. However, in addition to the conventional construction, this second embodiment provides an N-type implant 26 immediately below the BOX layer 14. These N-type implants 26 and 28 may also be described as deep implants, and are located in the regions underneath transistors 4 and 6 respectively.

The intent of these regional N-type implants is to provide “transistor islands” that are electrically isolated from one another. Isolating the regions below the active devices reduces the coupling that degrades RF performance.

Importantly, the N-type implants effectively tie up the free carriers from the interface states, and eliminate this free carrier mechanism for coupling. Since the N-type implants are placed immediately below the BOX layer, any free carriers generated in the P-type handle wafer can no longer travel freely at the interface of the BOX layer and P-type handle wafer.

Additionally, a P-type implant, if desirable, could be implemented as well. For example, a P-type regional implant may be located in an N-type bulk handle wafer.

The presently disclosed deep implants 26 and 28 (to suppress coupling) differ in both purpose and construction from the conventional ESD implants. Since the deep implants 26 and 28 are configured to suppress interface carriers, the placement and subsequent anneal of deep implants 26 and 28 are preferably tailored to suppress interface carriers. For example, the deep implants 26 and 28 of this second embodiment are preferably placed more precisely in the interface region than would an implant to form a diode under the BOX layer. In order to prevent the flow of free carriers and concomitant coupling, the deep implants must be placed directly under and in contact with the BOX layer. This is to prevent the carriers from moving freely along the handle wafer/BOX interfacial layer.

The doping concentrations of the deep implants 26 and 28 implant may also be tailored to provide maximum isolation capabilities. Typically the doping in the handle wafer under the BOX is a low concentration. The counter-doped regions would typically be low doping as well. The low doping of both the handle wafer and the isolation region increases the breakdown voltage between the regions as well as reduces the parasitic capacitance between the N and P doped regions.

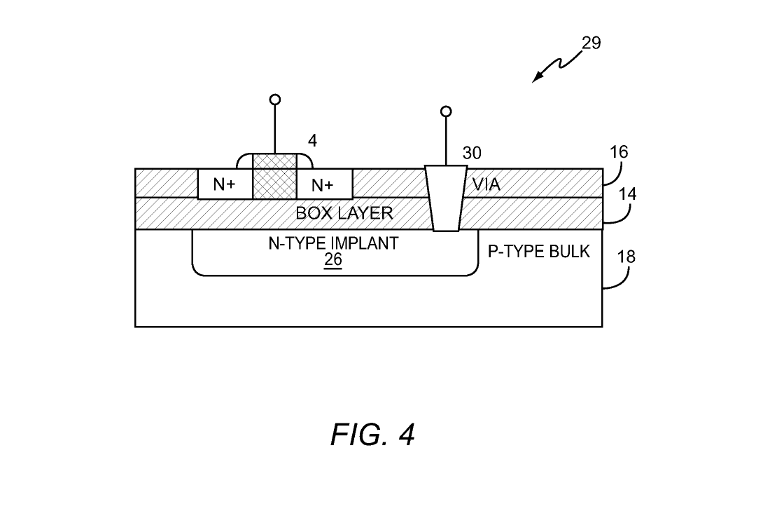

FIG. 4 illustrates a contacted sub-BOX N-type implant (third embodiment). FIG. 4 is similar to FIG. 3, but further comprising a via 30 providing an electrical path from N-type implant 26 through BOX layer 14 and through silicon layer 16. N-type implant 26 may be grounded or otherwise biased through the via. Other N-type implants (not shown) may be biased in the same way as N-type implant 26, or in a different way.

In addition, the various embodiments described above may be combined. For example, embodiments 1 and 2 and 3 could be combined, yielding a circuit having a deep NWELL 24 above BOX layer 14, an N-type implant 26 below BOX layer 14, and a via 30 (as shown in FIG. 4). Other such combinations are considered within the scope of the present disclosure.

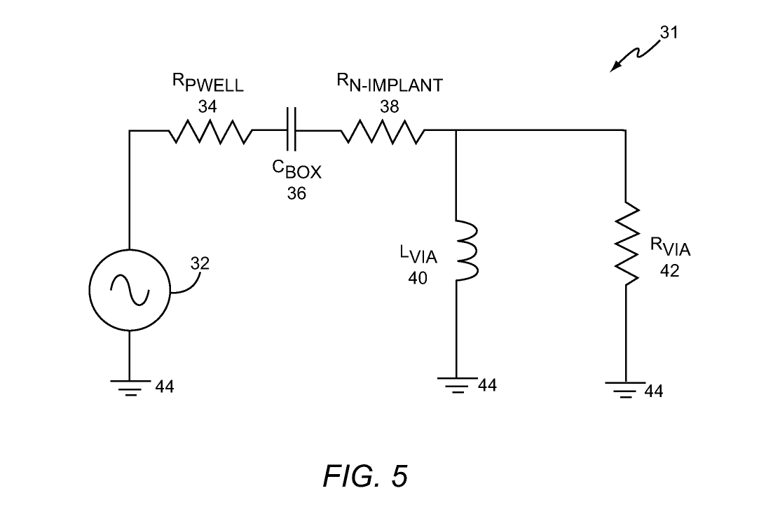

In FIG. 4, the ability to contact N-type implant 26 through via 30 can also allow for further engineering of the RF characteristics of this circuit. See FIG. 5 for additional discussion of the RF characteristics of this circuit.

FIG. 5 illustrates an electrical schematic of a contacted sub-BOX N-type implant (third embodiment). This schematic assumes that via 30 of FIG. 4 (third embodiment) is grounded, although via 30 may be biased to some nonzero voltage.

Specifically (and referring to FIGS. 4 and 5), an RF signal from transistor 4 is symbolized by signal generator 32, passes through R_{PWELL} 34 (the resistance of the PWELL 20 of transistor 4), then passes through C_{BOX} (the capacitance of BOX layer 14), then passes through R_{N-IMPLANT} (the resistance of N-type implant 26), then is coupled to ground 44 (or some other bias voltage which is not shown) through L_{VIA} (the inductance of via 30) and in parallel through R_{VIA} (the resistance of via 30). Undesired coupling of circuit elements may be reduced by de-tuning (first method) or by shielding (second method).

In a resonant circuit, tuning elements such as resistors and capacitors can be adjusted to maximize the transmission of particular frequencies. The opposite effect (de-tuning) is desired for the circuit elements in FIG. 5. To minimize the loss of signal to ground (insertion loss), the elements in this circuit may be de-tuned in order to impede the signal transfer to ground 44, particularly at the frequencies of interest for the circuit.

Referring to FIGS. 4 and 5, the two most easily tuned elements in the above circuit are the capacitance of the BOX layer 14 (C_{BOX}) and the resistance of buried N-type implant 26 (R_{N-IMPLANT}). Manipulation of C_{BOX} can be achieved by the added implanted layers. Specifically, a deep N-type implant above and/or below the BOX layer increases the effective thickness (and capacitance) of the dielectric BOX layer 14 because the bottom plate of the capacitor is handle wafer 18 (preferably P-type bulk silicon). The top plate of the capacitor is the PWELL under the gate of transistor 4 (see PWELL 20 in FIG. 2). The resistance of the buried layer (R_{N-IMPLANT}) can be adjusted by varying the implant dosage, thus manipulating C_{BOX}.

As discussed above, shielding is the second method of reducing or preventing coupling. RF shielding isolates RF components from each other. Since the implanted N-type regions can be contacted in embodiment 1 (deep NWELL 24 is contacted through N+ contact region 23 and side NWELL 22) and in embodiment 3 (N-type implant 26 may be contacted through via 30), these regions can be utilized as an RF “shield” to minimize or prevent the coupling through the bulk. Such a shield isolates the active devices (such as transistor 4 and transistor 6 in FIG. 3) from each other.

Proper design of either the parasitic element properties (to de-tune the circuit) or the shielding effect will require careful consideration of the circuit's construction. For example, while it may appear prudent to provide a very good ground 44 (through via 30) for the N-type implant 26, this good ground may lead to increased insertion loss since the RF signal that does couple to this N-type implant 26 is now shunted to ground very effectively.

As described in detail above, the present disclosure relates to reducing the coupling of the RF signal into the substrate (handle wafer) of the SOI structure. Reduction of coupling improves parameters such as: intermodulation distortion, insertion loss, harmonic distortion and the like. At least three different embodiments of the invention are described above. Each embodiment can be used to reduce coupling through reduction of the parasitic capacitance, or improved shielding, or both.

The concepts of this disclosure may be applicable to other RF SOI applications in addition to those described above. All such variations are considered to be within the scope of the present disclosure.

Those skilled in the art will recognize improvements and modifications to the present disclosure. All such improvements and modifications are considered within the scope of the concepts disclosed herein.

What is claimed is:

1. A low coupling SOI (Silicon-on-insulator) structure comprising:
a thick film silicon layer;
a BOX (buried oxide) layer located under the thick film silicon layer;
a handle layer located under the BOX layer;
a first NFET (N-type Field Effect Transistor) located in the thick film silicon layer, wherein the first NFET includes a first PWELL (P-type well); and
a first deep NWELL (N-type implant) located in the thick film silicon, located substantially directly under the first PWELL, and located above the BOX layer.

2. The low coupling SOI (Silicon-on-insulator) structure of claim 1,
wherein a top surface of the first deep NWELL physically contacts a bottom surface of the first PWELL; and
wherein a bottom surface of the first deep NWELL physically contacts a top surface of the BOX layer.

3. The low coupling SOI (Silicon-on-insulator) structure of claim 1, further comprising:
a first side NWELL (N-type implant) substantially enclosing all sides of the first PWELL, and
a first N+ contact region,
wherein a bottom surface of the first side NWELL physically contacts a top surface of the first deep NWELL, and
wherein a top surface of the first side NWELL physically contacts a bottom surface of the first N+ contact region.

4. The low coupling SOI (Silicon-on-insulator) structure of claim 1 further comprising:
a first side NWELL (N-type implant) substantially enclosing all sides of the first PWELL, and
wherein the first deep NWELL and the first side NWELL fully enclose the first PWELL, such that the first PWELL is isolated from the thick film silicon film and is isolated from the BOX layer.

5. The low coupling SOI (Silicon-on-insulator) structure of claim 3,
wherein a top surface of the first N+ contact region is biased.

6. The low coupling SOI (Silicon-on-insulator) structure of claim 3,
wherein a top surface of the first N+ contact region is grounded.

7. The low coupling SOI (Silicon-on-insulator) structure of claim 3,
wherein the first side NWELL and the first deep NWELL have a same concentration of N-type doping impurities.

8. The low coupling SOI (Silicon-on-insulator) structure of claim 3,
wherein the first side NWELL has a higher concentration of N-type doping impurities than the first deep NWELL.

9. The low coupling SOI (Silicon-on-insulator) structure of claim 3,
wherein the first side NWELL has a lower concentration of N-type doping impurities than the first deep NWELL.

10. The low coupling SOI (Silicon-on-insulator) structure of claim 3,
wherein the first deep NWELL is located directly below the first PWELL, and extends sideways beyond the first PWELL in all side directions.

11. The low coupling SOI (Silicon-on-insulator) structure of claim 3, further comprising:
a second NFET (N-type Field Effect Transistor) located in the thick film silicon layer, wherein the second NFET includes a second PWELL (P-type well); and
a second deep NWELL (N-type implant) located in the thick film silicon layer, located substantially under the second PWELL, and located above the BOX layer;
a second side NWELL (N-type implant) substantially enclosing the sides of the second PWELL, and
wherein a first portion of the thick film silicon layer separates the first deep NWELL and the first side NWELL from the second deep NWELL and the second side NWELL.

12. The low coupling SOI (Silicon-on-insulator) structure of claim 3, further comprising:
a first wafer N-type implant located in the handle layer, and located substantially under the first PWELL.

13. The low coupling SOI (Silicon-on-insulator) structure of claim 12, further comprising:
a first via, wherein the first via contacts the first wafer N-type implant and penetrates through the BOX layer and through the thick film silicon layer.

14. A low coupling SOI (Silicon-on-insulator) structure comprising:
a film silicon layer;
a BOX (buried oxide) layer located under the film silicon layer;
a handle layer located under the BOX layer;
a first NFET (N-type Field Effect Transistor) located in the film silicon layer, wherein the first NFET includes a first PWELL (P-type well); and
a first wafer N-type implant located in the handle layer, and located substantially under the first PWELL.

15. The low coupling SOI (Silicon-on-insulator) structure of claim 14,
wherein a top surface of the first wafer N-type implant contacts a bottom surface of the BOX layer.

16. The low coupling SOI (Silicon-on-insulator) structure of claim 14,
wherein the handle layer is P-type bulk silicon.

17. The low coupling SOI (Silicon-on-insulator) structure of claim 14, further comprising:
a second NFET (N-type Field Effect Transistor) located in the film silicon layer, wherein the second NFET includes a second PWELL (P-type well); and
a second wafer N-type implant located in the handle layer, and located substantially under the second PWELL.

18. The low coupling SOI (Silicon-on-insulator) structure of claim 17,
wherein a first portion of the P-type bulk silicon of the handle layer isolates the first wafer N-type implant from the second wafer N-type implant.

19. The low coupling SOI (Silicon-on-insulator) structure of claim 12,
wherein the sides of the first wafer N-type implant extend sideways beyond the first PWELL.

20. The low coupling SOI (Silicon-on-insulator) structure of claim 19, further comprising:
a first via, wherein the first via contacts the first wafer N-type implant and penetrates through the BOX layer and through the thick film silicon layer.

21. A low coupling SOI (Silicon-on-insulator) structure comprising:
a thick film silicon layer;
a BOX (buried oxide) layer located under the thick film silicon layer;
a handle layer located under the BOX layer;
a first PFET (P-type Field Effect Transistor) located in the thick film silicon layer, wherein the first PFET includes a first NWELL (N-type well); and
a first deep PWELL (P-type implant) located in the thick film silicon, located substantially directly under the first NWELL, and located above the BOX layer.
